(19) United States
(12) Patent Application Publication
(10) Pub. No.: US 2026/0042235 A1
(43) Pub. Date: Feb. 12, 2026

(54) APPARATUS AND METHOD FOR MANUFACTURING DISPLAY DEVICE AND ELECTRONIC DEVICE INCLUDING DISPLAY DEVICE

(71) Applicant: Samsung Display Co., LTD., Yongin-si (KR)

(72) Inventors: SANGHYUK LEE, Yongin-si (KR); DEOK-HEUNG KIM, Yongin-si (KR); DONGHYUN KIM, Yongin-si (KR); SUNGLAE KIM, Yongin-si (KR); SUKBEOM YOU, Yongin-si (KR)

(21) Appl. No.: 19/272,080

(22) Filed: Jul. 17, 2025

(30) Foreign Application Priority Data
Aug. 9, 2024 (KR) 10-2024-0106920

(51) Int. Cl. B26D 1/00; H10K 59/12; H10K 59/80

(52) U.S. Cl. CPC B26D 1/0006; H10K 59/1201; B26D 2001/002; H10K 59/873; H10K 59/8791

(57) ABSTRACT

An apparatus for manufacturing a display device includes: a guide plate provided to contact a display panel; a cutting member which cuts a resin layer formed on the display panel along an edge of the display panel; a first tank which accommodates a cleaning solution for removing a residue of the resin layer adhered to the cutting member; a plasma treatment part which performs a plasma treatment on the cutting member; and a second tank which accommodates a hydrophobic coating solution for coating the cutting member with a hydrophobic material.

This application claims priority to Korean Patent Application No. 10-2024-0106920, filed on Aug. 9, 2024, and all the benefits accruing therefrom under 35 U.S. C. § 119, the content of which in its entirety is herein incorporated by reference.

### BACKGROUND

### 1. Field

The disclosure relates generally to an apparatus for manufacturing a display device. More particularly, the disclosure relates to an apparatus for manufacturing a display device, a method for manufacturing a display device using the apparatus and an electronic device including a display device manufactured by the method.

### 2. Description of the Related Art

With the development of information technology, the importance of a display device, which is a connection medium between a user and information, has been highlighted. For example, the use of display devices such as liquid crystal display (LCD) device, organic light emitting diode (OLED) display device, plasma display panel (PDP) device, quantum dot display device or the like is increasing.

The display device may include a display panel and a functional member arranged on the display panel. For example, the functional member may be an anti-reflection layer to reduce external light reflection of the display device, a cover window to protect the display panel, or the like. As an adhesive member for attaching the display panel and the functional member, an optically clear resin may be used. The optically clear resin may be formed by radiating ultraviolet light on a resin layer including an oligomer, a monomer, a photopolymerization initiator, or the like.

### SUMMARY

Embodiments provide an apparatus for manufacturing a display device in which a process defect is effective prevented or substantially minimized.

Embodiments provide a method for manufacturing a display device using the apparatus for manufacturing the display device.

Embodiments provide an electronic device including a display device manufactured by the method.

An apparatus for manufacturing a display device according to an embodiment of the disclosure includes: a guide plate provided to contact a display panel; a cutting member which cuts a resin layer formed on the display panel along an edge of the display panel; a first tank which accommodates a cleaning solution for removing a residue of the resin layer adhered to the cutting member; a plasma treatment part which performs a plasma treatment on the cutting member; and a second tank which accommodates a hydrophobic coating solution for coating the cutting member with a hydrophobic material.

In an embodiment, the cutting member may cut the resin layer in a way such that a side surface of the resin layer is substantially perpendicular to an upper surface of the resin layer.

In an embodiment, the cutting member may cut the resin layer in a way such that a side surface of the resin layer is substantially aligned with the edge of the display panel in a thickness direction of the display panel.

In an embodiment, the hydrophobic coating solution may include octadecyltrichlorosilane.

In an embodiment, the cutting member may include a body portion and a blade portion which is connected to the body portion and cuts the resin layer. The hydrophobic material may be coated on the blade portion.

In an embodiment, the hydrophobic material may include a siloxane-based polymer or a fluorine-based polymer.

In an embodiment, the hydrophobic material may reduce an adhesive force between the cutting member and the resin layer.

A method for manufacturing a display device according to an embodiment of the disclosure includes: contacting a guide plate with a display panel and an anti-reflection layer arranged on the display panel; forming a resin layer on the guide plate and the anti-reflection layer; cutting the resin layer along an edge of the display panel using a cutting member; removing a residue of the resin layer adhered to the cutting member; performing a plasma treatment on the cutting member; coating a hydrophobic material on the cutting member; and cutting a resin layer formed on another anti-reflection layer different from the anti-reflection layer using the cutting member coated with the hydrophobic material.

In an embodiment, the coating the hydrophobic material on the cutting member may include immersing the cutting member in a hydrophobic coating solution.

In an embodiment, the hydrophobic coating solution may include octadecyltrichlorosilane.

In an embodiment, the cutting member may include a body portion and a blade portion which is connected to the body portion and cuts the resin layer. The hydrophobic material may be coated on the blade portion.

In an embodiment, the hydrophobic material may include a siloxane-based polymer or a fluorine-based polymer.

In an embodiment, the cutting member coated with the hydrophobic material may cut the resin layer in a way such that a side surface of the resin layer is substantially perpendicular to an upper surface of the resin layer.

In an embodiment, the cutting member coated with the hydrophobic material may cut the resin layer in a way such that a side surface of the resin layer is substantially aligned with the edge of the display panel in a thickness direction of the display panel.

In an embodiment, in the forming the resin layer on the guide plate and the anti-reflection layer, the resin layer may include a first portion which overlaps the anti-reflection layer in a plan view and a second portion which is connected to the first portion and overlaps the guide plate in the plan view. The first portion of the resin layer may have a substantially flat upper surface.

In an embodiment, a side surface of the guide plate may contact a side surface of the display panel and a side surface of the anti-reflection layer in the contacting the guide plate with the display panel and the anti-reflection layer.

In an embodiment, the guide plate may entirely surround the display panel and the anti-reflection layer in a plan view in the contacting the guide plate with the display panel and the anti-reflection layer.

In an embodiment, a level of an upper surface of the guide plate may be substantially the same as a level of an upper surface of the anti-reflection layer.

In an embodiment, the method may further include separating the guide plate from the display panel and the anti-reflection layer and cleaning the guide plate after the cutting the resin layer along the edge of the display panel.

An electronic device according to an embodiment of the disclosure includes: a display device manufactured by the method described above; and a processor which transmits an image data signal and an input control signal to the display device.

An apparatus for manufacturing a display device according to an embodiment of the disclosure may include a guide plate provided to contact a display panel, a cutting member which cuts a resin layer formed on the display panel along an edge of the display panel, a plasma treatment part which performs plasma treatment on the cutting member, and a tank which accommodates a hydrophobic coating solution for coating the cutting member with a hydrophobic material.

In such an embodiment, as the cutting member is plasma treated by the plasma treatment part, the hydrophobic material may be more smoothly adsorbed on the cutting member. As the cutting member is coated with the hydrophobic material, the phenomenon of a residue sticking to the cutting member in the process of cutting the resin layer may be suppressed.

Accordingly, when the resin layer is cut using the cutting member coated with the hydrophobic material, a side surface of the resin layer (i.e., a cut surface of the resin layer) may be substantially aligned with an edge of the display panel in a thickness direction of the display panel. In addition, an angle formed between the side surface of the resin layer and an upper surface of the resin layer may be substantially a right angle. As a result, the formation of a burr on the side surface of the resin layer may be effectively prevented, and a process defect caused by the burr may be suppressed.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the disclosure.

FIG. 2 is a cross-sectional view illustrating the display device of FIG. 1.

FIG. 3 is an enlarged cross-sectional view of area A of FIG. 2.

FIGS. 4, 5, 6, 7, 8, 9, 10, 11, 12, 13, 14, 15, 16, 17, and 18 are views illustrating a method for manufacturing a display device according to an embodiment of the disclosure.

FIG. 19 is a block diagram of an electronic device according to an embodiment of the disclosure.

FIG. 20 is a schematic diagram of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings. The same or like reference numerals are used for the same or like components in the drawings, and any repetitive detailed descriptions of the same or like components will be omitted or simplified.

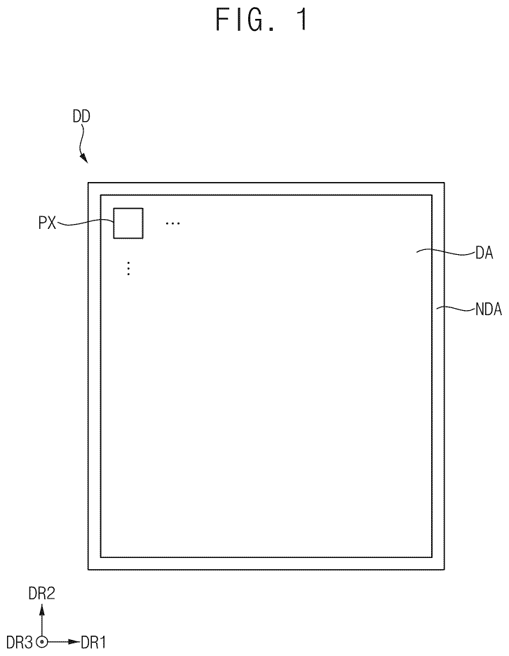

FIG. 1 is a plan view illustrating a display device according to an embodiment of the disclosure.

In the disclosure, a plane may be defined by a first direction DR1 and a second direction DR2 intersecting the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2. As used herein, a “plan view”is a view when viewed in the third direction DR3.

Referring to FIG. 1, the display device DD according to an embodiment of the disclosure may include a display area DA and a non-display area NDA.

The display area DA may be defined as an area that displays an image by generating light or adjusting the transmittance of light provided from an external light source. A plurality of pixels PX may be arranged in the display area DA. Each of the pixels PX may generate light in response to a driving signal. In an embodiment, for example, the pixels PX may be arranged in a matrix form along the first direction DR1 and the second direction DR2.

The non-display area NDA may be defined as an area that does not display an image. The non-display area NDA may surround at least a portion of the display area DA in a plan view. In an embodiment, for example, the non-display area NDA may entirely surround the display area DA in a plan view. A driving chip and a plurality of pads that provide the driving signal to the pixels PX may be arranged in the non-display area NDA.

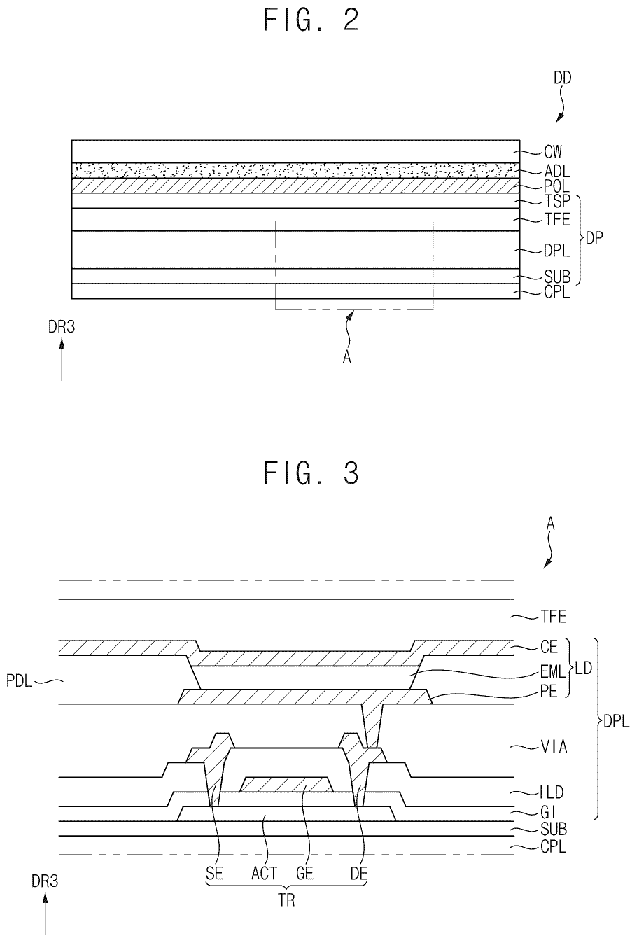

FIG. 2 is a cross-sectional view illustrating the display device of FIG. 1. FIG. 3 is an enlarged cross-sectional view of area A of FIG. 2.

Referring to FIGS. 2 and 3, an embodiment of the display device DD may include a display panel DP, a cover panel CPL, an anti-reflection layer POL, and a cover window CW. The display panel DP may include a substrate SUB, a display layer DPL, an encapsulation layer TFE, and a touch sensing layer TSP.

The substrate SUB may include a transparent material or an opaque material. The substrate SUB may include or be formed of a transparent resin substrate. In an embodiment, for example, the transparent resin substrate may be a polyimide substrate. In such an embodiment, the polyimide substrate may include a first organic layer, a first barrier layer, a second organic layer, etc. In an embodiment, the substrate SUB may include a quartz substrate (e.g., a synthetic quartz substrate, a fluorine-doped quartz substrate, or the like), a calcium fluoride substrate, a soda-lime glass substrate, a non-alkali glass substrate, or the like. These may be used alone or in combination with each other.

The cover panel CPL may be arranged under the substrate SUB. The cover panel CPL may protect the substrate SUB from external impact. In addition, the cover panel CPL may prevent scratches from occurring on back surfaces of the components included in the display panel DP during a manufacturing process of the display panel DP.

The display layer DPL may be arranged on the substrate SUB. In an embodiment, as illustrated in FIG. 3, the display layer DPL may include a transistor TR, a gate insulating layer GI, an inter-layer insulating layer ILD, a via-insulating layer VIA, a light-emitting element LD, and a pixel defining layer PDL. The transistor TR may include an active pattern ACT, a gate electrode GE, a source electrode SE, and a drain electrode DE. The light-emitting element LD may include a pixel electrode PE, a light-emitting layer EML, and a common electrode CE.

A buffer layer may be arranged between the substrate SUB and the display layer DPL. The buffer layer may prevent diffusion of metal atoms or impurities from the substrate SUB to an upper structure (e.g., the transistor TR, the light-emitting element LD, or the like). In addition, the buffer layer may obtain the substantially uniform active pattern ACT by controlling a heat transfer rate during a crystallization process for forming the active pattern ACT. In an embodiment, for example, the buffer layer may include an inorganic insulating material. In another embodiment, the buffer layer may be omitted.

The active pattern ACT may be arranged on the substrate SUB. The active pattern ACT may include an oxide semiconductor, a silicon semiconductor, an organic semiconductor, or the like. In an embodiment, for example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), or the like. These may be used alone or in combination with each other. The silicon semiconductor may include amorphous silicon, polycrystalline silicon, or the like. The active pattern ACT may include a source area, a drain area, and a channel area positioned between the source area and the drain area.

The gate insulating layer GI may be arranged on the substrate SUB and the active pattern ACT. In an embodiment, for example, the gate insulating layer GI may cover the active pattern ACT on the substrate SUB and may be arranged along the profile of the active pattern ACT with a substantially uniform thickness. The gate insulating layer GI may include an inorganic insulating material. Examples of the inorganic insulating material that may be used as the gate insulating layer GI may include silicon oxide (SiOₓ), silicon nitride (SiNₓ), silicon oxynitride (SiOₓN_{y}), or the like. These may be used alone or in combination with each other. The gate insulating layer GI may electrically insulate the active pattern ACT from the gate electrode GE.

The gate electrode GE may be arranged on the gate insulating layer GI. The gate electrode GE may overlap the channel area of the active pattern ACT in the third direction DR3. The gate electrode GE may include a metal, an alloy, a conductive metal nitride, a conductive metal oxide, a transparent conductive oxide, or the like. Examples of materials that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The inter-layer insulating layer ILD may be arranged on the gate insulating layer GI and the gate electrode GE. In an embodiment, for example, the inter-layer insulating layer ILD may cover the gate electrode GE on the gate insulating layer GI and may be arranged along the profile of the gate electrode GE with a substantially uniform thickness. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), or the like. These may be used alone or in combination with each other. The inter-layer insulating layer ILD may electrically insulate the gate electrode GE from the source electrode SE. In addition, the inter-layer insulating layer ILD may electrically insulate the gate electrode GE from the drain electrode DE.

The source electrode SE and the drain electrode DE may be arranged on the inter-layer insulating layer ILD. The source electrode SE may be connected to the source area of the active pattern ACT through a contact hole defined through the gate insulating layer GI and the inter-layer insulating layer ILD. The drain electrode DE may be connected to the drain area of the active pattern ACT through a contact hole defined through the gate insulating layer GI and the inter-layer insulating layer ILD. Each of the source electrode SE and the drain electrode DE may include a metal, an alloy, a conductive metal nitride, a conductive metal oxide, a transparent conductive oxide, or the like. These may be used alone or in combination with each other.

Accordingly, the transistor TR including the active pattern ACT, the gate electrode GE, the source electrode SE, and the drain electrode DE may be disposed or formed on the substrate SUB.

The via-insulating layer VIA may be arranged on the inter-layer insulating layer ILD. In an embodiment, for example, the via-insulating layer VIA may cover the source electrode SE and the drain electrode DE on the inter-layer insulating layer ILD and may be arranged with a relatively thick thickness. The via-insulating layer VIA may have a substantially flat upper surface. The via-insulating layer VIA may include an organic insulating material. Examples of the organic insulating material that may be used as the via-insulating layer VIA may include a photoresist, a polyacryl-based resin, a polyimide-based resin, a polyamide-based resin, a siloxane-based resin, an acryl-based resin, an epoxy-based resin, or the like. These may be used alone or in combination with each other.

The pixel electrode PE may be arranged on the via-insulating layer VIA. The pixel electrode PE may be connected to the source electrode SE or the drain electrode DE through a contact hole defined through the via-insulating layer VIA. Accordingly, the pixel electrode PE may be electrically connected to the transistor TR. The pixel electrode PE may include a metal, an alloy, a conductive metal nitride, a conductive metal oxide, a transparent conductive oxide, or the like. These may be used alone or in combination with each other. In an embodiment, for example, the pixel electrode PE may serve as an anode electrode.

The pixel defining layer PDL may be arranged on the via-insulating layer VIA. The pixel defining layer PDL may cover an edge of the pixel electrode PE and may expose a portion of the pixel electrode PE. The pixel defining layer PDL may include an organic insulating material. Examples of the organic insulating material that may be used as the pixel defining layer PDL may include a photoresist, a polyacryl-based resin, a polyimide-based resin, a polyamide-based resin, a siloxane-based resin, an acryl-based resin, an epoxy-based resin, or the like. These may be used alone or in combination with each other.

The light-emitting layer EML may be arranged on the pixel electrode PE. The light-emitting layer EML may emit light having a specific color (e.g., red, green, or blue). In an embodiment, the light-emitting layer EML may include at least one of an organic light-emitting material and a quantum dot. In an embodiment, for example, the light-emitting layer EML may include an organic light-emitting material including a fluorescent material or a phosphorescent material that emits red light, green light, or blue light. In an embodiment, for example, the light-emitting layer EML may have a single-layer structure including one light-emitting structure. However, the disclosure is not limited thereto, and the light-emitting layer EML may have a tandem structure in which a plurality of light-emitting structures are stacked.

The common electrode CE may be arranged on the pixel defining layer PDL and the light-emitting layer EML. In an embodiment, for example, the common electrode CE may cover the pixel defining layer PDL and the light-emitting layer EML and may be arranged along the profiles of the pixel defining layer PDL and the light-emitting layer EML with a substantially uniform thickness. The common electrode CE may include a metal, an alloy, a conductive metal nitride, a conductive metal oxide, a transparent conductive oxide, or the like. These may be used alone or in combination with each other. In an embodiment, for example, the common electrode CE may serve as a cathode electrode.

Accordingly, the light-emitting element LD including the pixel electrode PE, the light-emitting layer EML, and the common electrode CE may be disposed or formed on the via-insulating layer VIA.

The encapsulation layer TFE may be arranged on the common electrode CE. The encapsulation layer TFE may prevent impurities, moisture, or the like from penetrating into the light-emitting element LD from the outside. The encapsulation layer TFE may include at least one inorganic encapsulation layer and at least one organic encapsulation layer. In an embodiment, for example, the inorganic encapsulation layer may include silicon oxide (SiOₓ), silicon nitride (SiNₓ), silicon oxynitride (SiOₓN_{y}), or the like. These may be used alone or in combination with each other. In an embodiment, for example, the organic encapsulation layer may include a cured polymer such as polyacrylate.

The encapsulation layer TFE may have a structure in which the inorganic encapsulation layer and the organic encapsulation layer are alternately stacked. In an embodiment, for example, the encapsulation layer TFE may have a three-layer structure in which two inorganic encapsulation layers and one organic encapsulation layer are alternately stacked, but the disclosure is not limited thereto.

In an embodiment, as illustrated in FIG. 2, the touch sensing layer TSP may be arranged on the encapsulation layer TFE. The touch sensing layer TSP may detect a user's touch. In an embodiment, for example, the touch sensing layer TSP may acquire coordinate information based on an external input, such as the user's touch. In an embodiment, for example, the touch sensing layer TSP may acquire coordinate information based on the external input using a mutual capacitance method and/or a self-capacitance method. The touch sensing layer TSP may include sensing electrodes, routing lines connected to the corresponding sensing electrodes, and at least one sensing insulating layer.

The anti-reflection layer POL may be arranged on the touch sensing layer TSP. The anti-reflection layer POL may reduce the external light reflection of the display device DD. As the external light reflection is reduced, the visibility of the display device DD may be improved. In an embodiment, the anti-reflection layer POL may include a polarizer and/or a phase retarder. In an embodiment, for example, the anti-reflection layer POL may include a polarizer of a stretched film type and/or a phase retarder. In an embodiment, the anti-reflection layer POL may include color filters and a black matrix arranged between the color filters. The color filters may be arranged in consideration of a light-emitting color of the light-emitting layer EML.

The cover window CW may be arranged on the anti-reflection layer POL. In an embodiment, the cover window CW may be attached to an upper surface of the anti-reflection layer POL through an adhesive layer ADL. The cover window CW may cover and protect the display panel DP. The cover window CW may include a transparent material to allow light provided from the light-emitting layer EML to pass therethrough to the outside of the display device DD. In an embodiment, for example, the cover window CW may include glass or plastic.

The adhesive layer ADL may be arranged between the anti-reflection layer POL and the cover window CW. The adhesive layer ADL may attach the anti-reflection layer POL and the cover window CW. In an embodiment, for example, the adhesive layer ADL may include a pressure sensitive adhesive (PSA) film, an optically clear adhesive (OCA) film, or an optically clear resin (OCR). In an embodiment, the adhesive layer ADL may include an optically clear resin (OCR).

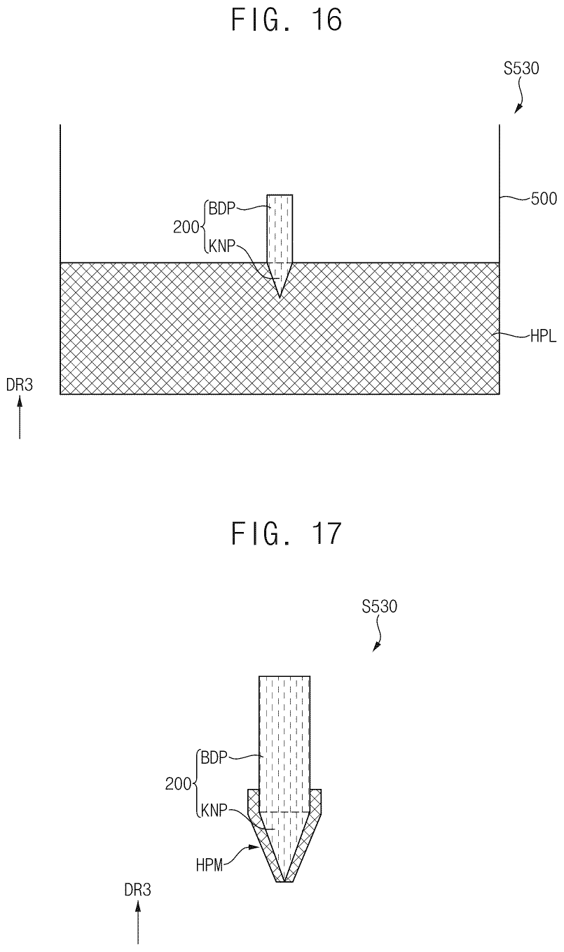

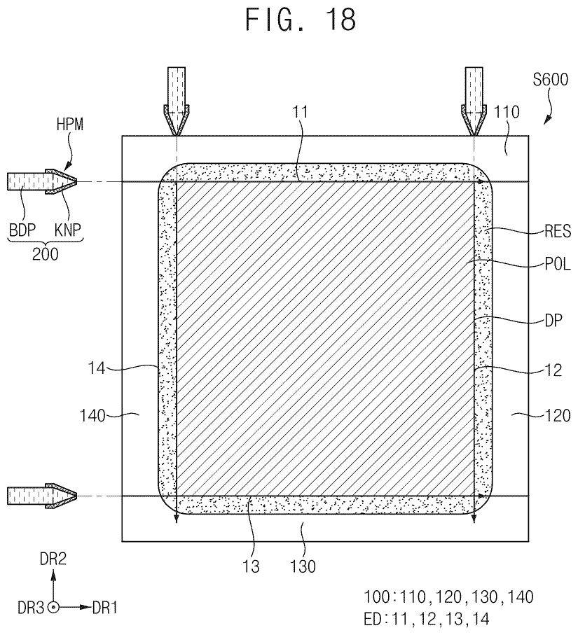

In an embodiment, in a cross-section, a side surface of the adhesive layer ADL may be substantially aligned with an edge of the display panel DP in a thickness direction (or the third direction DR3) of the display panel DP. In an embodiment, for example, in the cross-section, the side surface of the adhesive layer ADL may be substantially with an edge of the display panel DP in the third direction DR3. In addition, in the cross-section, an angle formed between the side surface of the adhesive layer ADL and an upper surface of the adhesive layer ADL may be substantially a right angle. To form the adhesive layer ADL in a way such that the angle becomes a right angle, a method for manufacturing a display device according to an embodiment of the disclosure may include cutting a resin layer (RES, refer to FIG. 18) using a blade portion (KNP, refer to FIG. 18) coated with a hydrophobic material (HPM, refer to FIG. 18). A detailed features thereof will be described below with reference to FIGS. 16, 17, and 18.

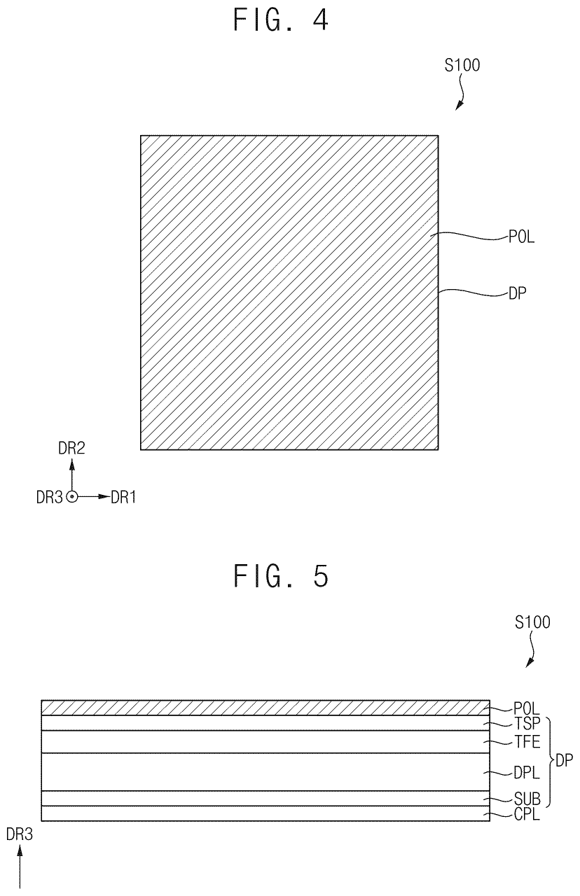

FIGS. 4, 5, 6, 7, 8, 9, 10, 11, 12, 13, 14, 15, 16, 17, and 18 are views illustrating a method for manufacturing a display device according to an embodiment of the disclosure. Particularly, FIGS. 4, 6, 8, 10, 12, and 18 are plan views illustrating the method for manufacturing the display device according to an embodiment of the disclosure, and FIGS. 5, 7, 9, 11, 13, 14, 15, 16, and 17 are cross-sectional views illustrating the method for manufacturing the display device according to an embodiment of the disclosure.

Referring to FIGS. 4 and 5, in an embodiment of a method for manufacturing a display device, the display panel DP and the anti-reflection layer POL may be provided (S100).

The display panel DP may include the substrate SUB, the display layer DPL, the encapsulation layer TFE, and the touch sensing layer TSP. The display layer DPL may be arranged on the substrate SUB. The display layer DPL may include the transistor TR, the gate insulating layer GI, the inter-layer insulating layer ILD, the via-insulating layer VIA, the light-emitting element LD, and the pixel defining layer PDL as described above with reference to FIG. 3. The encapsulation layer TFE may be arranged on the display layer DPL. The encapsulation layer TFE may cover the display layer DPL. The touch sensing layer TSP may be arranged on the encapsulation layer TFE.

The anti-reflection layer POL may be arranged on the display panel DP. In an embodiment, the anti-reflection layer POL may include a polarizer and/or a phase retarder. In an embodiment, for example, the anti-reflection layer POL may include a polarizer of a stretched film type and/or phase retarder.

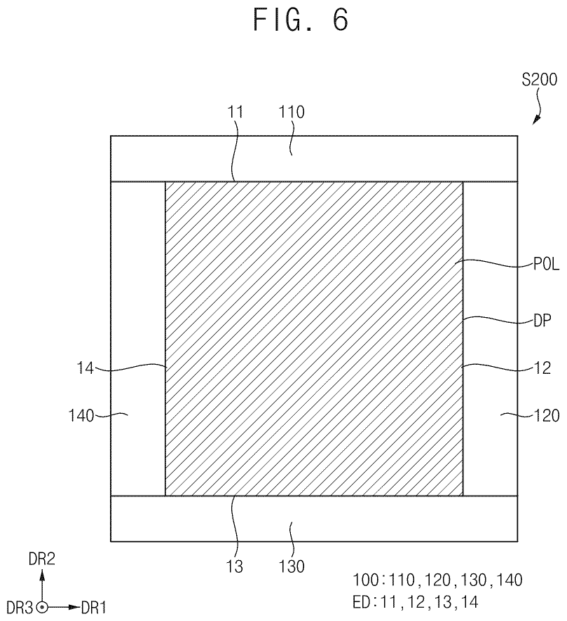

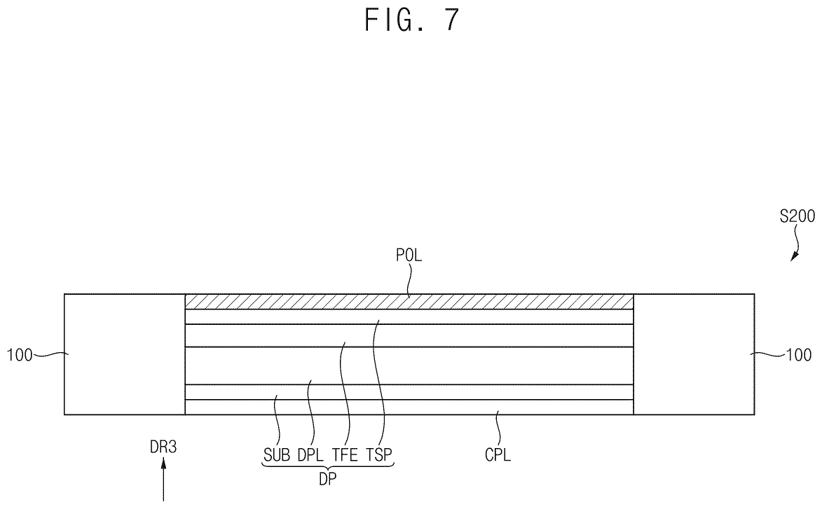

Referring to FIGS. 6 and 7, in an embodiment of a method for manufacturing a display device, a guide plate 100 may contact the display panel DP and the anti-reflection layer POL (S200). In an embodiment, for example, a side surface of the guide plate 100 may contact a side surface of the display panel DP and a side surface of the anti-reflection layer POL.

The guide plate 100 may have a substantially flat upper surface. In an embodiment, as illustrated in FIG. 7, a level of the upper surface of the guide plate 100 may be substantially the same as a level of an upper surface of the anti-reflection layer POL, that is, the upper surface of the guide plate 100 and the upper surface of the anti-reflection layer POL may be substantially on a same plane.

The guide plate 100 may entirely surround the display panel DP and the anti-reflection layer POL in a plan view. The guide plate 100 may include a first plate 110, a second plate 120, a third plate 130, and a fourth plate 140. In an embodiment, for example, the display panel DP may have an edge ED including a first side 11 extending in the first direction DR1, a second side 12 contacting the first side 11 and extending in the second direction DR2, a third side 13 facing and extending parallel to the first side 11, and a fourth side 14 facing and extending parallel to the second side 12. The first plate 110 may contact the first side 11 of the display panel DP. The second plate 120 may contact the first plate 110 and the second side 12 of the display panel DP. The third plate 130 may contact the second plate 120 and the third side 13 of the display panel DP. The fourth plate 140 may contact the first plate 110, the third plate 130, and the fourth side 14 of the display panel DP. Accordingly, the guide plate 100 may entirely surround the edge ED of the display panel DP in a plan view.

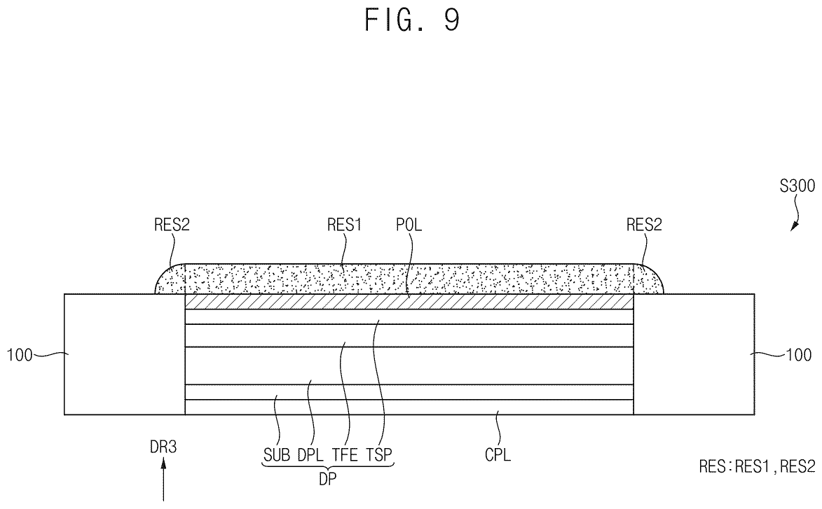

The guide plate 100 may effectively prevent a resin layer (RES, refer to FIG. 9) having fluidity from flowing down to an outer side of the display panel DP in forming the resin layer RES on the anti-reflection layer POL (S300) described below.

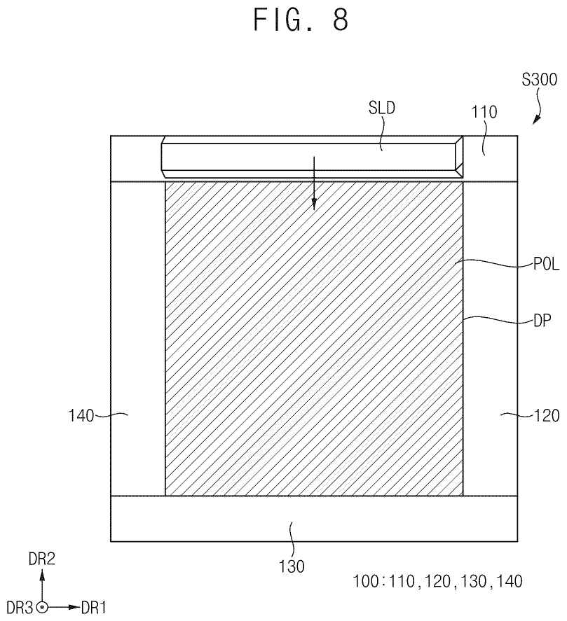

Referring to FIGS. 8 and 9, in an embodiment of a method for manufacturing a display device, the resin layer RES may be formed on the anti-reflection layer POL (S300).

In an embodiment, the resin layer RES may be formed by a slit coating method. In an embodiment, for example, the resin layer RES may be applied on the anti-reflection layer POL by a slit die SLD. The slit die SLD may move in the second direction DR2 or in an opposite direction of the second direction DR2. However, the disclosure is not limited thereto. In an embodiment, the resin layer RES may be applied on the anti-reflection layer POL by an inkjet printing method.

The resin layer RES may include an oligomer, a monomer, a photopolymerization initiator, and a solvent. When the resin layer RES is irradiated with ultraviolet light, the photopolymerization initiator may initiate a polymerization reaction between the oligomer and the monomer. The photopolymerization initiator may include at least one selected from a radical type initiator and a cationic type initiator.

After the resin layer RES is applied on the anti-reflection layer POL, the resin layer RES may be cured by irradiating the resin layer RES with ultraviolet light. That is, as the resin layer RES is irradiated with ultraviolet light, the photopolymerization initiator included in the resin layer RES may be degraded, and a polymerization reaction between the oligomer and the monomer may proceed. Accordingly, the resin layer RES may include a polymer in which the oligomer and the monomer are covalently bonded to each other. The cured resin layer RES may have the double-sided adhesive property. That is, the cured resin layer RES may be an optically clear resin.

The resin layer RES may overlap the anti-reflection layer POL and a portion of the guide plate 100 adjacent to the anti-reflection layer POL. In an embodiment, for example, the resin layer RES may contact the upper surface of the anti-reflection layer POL and an upper surface of a portion of the guide plate 100 adjacent to the anti-reflection layer POL.

In an embodiment, as illustrated in FIG. 9, the resin layer RES may include a first portion RES1 and a second portion RES2 connected to the first portion RES1. The first portion RES1 of the resin layer RES may overlap the display panel DP and the anti-reflection layer POL in a plan view. The first portion RES1 of the resin layer RES may have a substantially flat upper surface. The second portion RES2 of the resin layer RES may overlap the guide plate 100 in a plan view. In a cross-section, the second portion RES2 of the resin layer may have a convex curved surface.

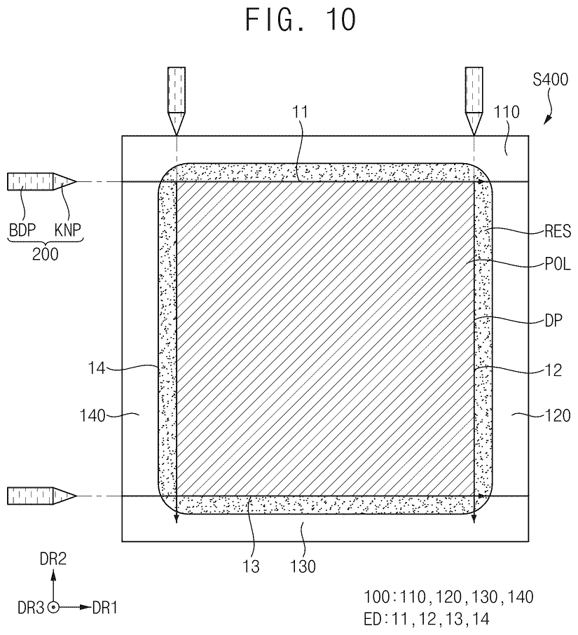

Referring to FIGS. 10, 11, 12, and 13, in an embodiment of a method for manufacturing a display device, the resin layer RES may be cut along the edge ED of the display panel DP (S400). In an embodiment, a cutting member 200 may cut the resin layer RES along the edge ED of the display panel DP.

The cutting member 200 may include a body portion BDP and a blade portion KNP connected to the body portion BDP. The blade portion KNP may be a portion that directly contacts the resin layer RES and cuts the resin layer RES. In an embodiment, for example, the cutting member 200 may move in the first direction DR1 and in an opposite direction of the first direction DR1. Accordingly, the cutting member 200 may cut a portion of the resin layer RES that overlaps the first side 11 and the third side 13 of the display panel DP in a plan view. In addition, the cutting member 200 may move in the second direction DR2 and in the opposite direction of the second direction DR2. Accordingly, the cutting member 200 may cut a portion of the resin layer RES that overlaps the second side 12 and the fourth side 14 of the display panel DP in a plan view. In other words, the cutting member 200 may cut a boundary portion between the first portion RES1 of the resin layer RES and the second portion RES2 of the resin layer RES.

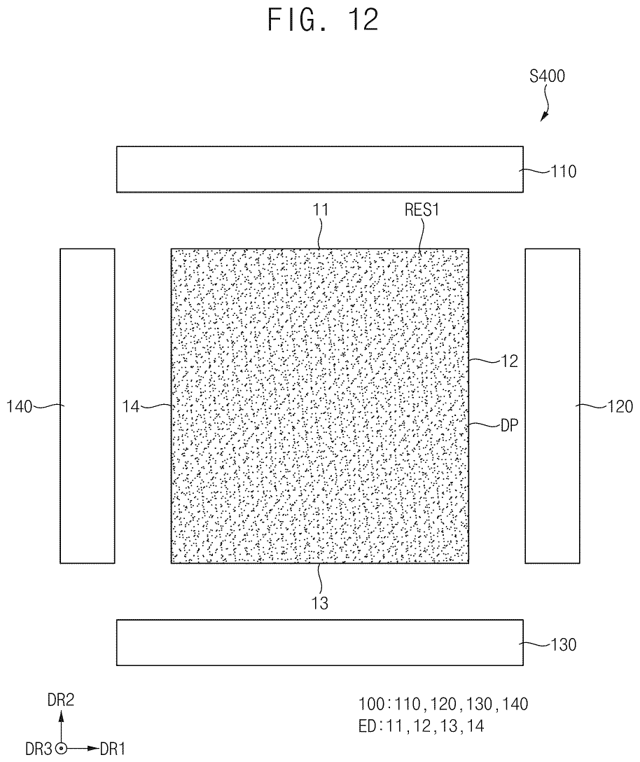

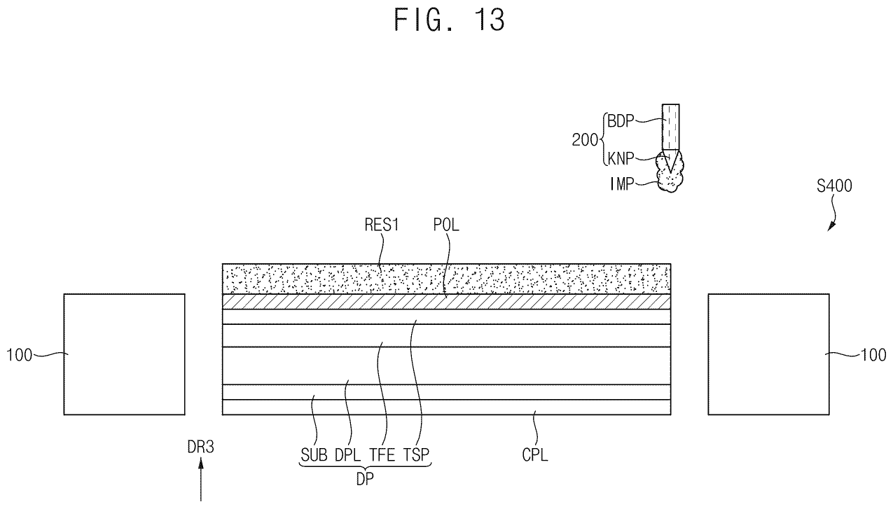

In an embodiment, as illustrated in FIGS. 12 and 13, the first portion RES1 of the resin layer RES that overlaps the display panel DP and the anti-reflection layer POL in a plan view may remain, and the second portion RES2 of the resin layer RES that overlaps the guide plate 100 in a plan view may be removed.

As the resin layer RES is cut by the blade portion KNP of the cutting member 200, in a cross-section, a side surface of the first portion RES1 of the resin layer RES may be substantially aligned with an edge of the display panel DP in the thickness direction of the display panel DP. In an embodiment, for example, in the cross-section, the side surface of the first portion RES1 of the resin layer may be substantially aligned with an edge of the display panel DP in the third direction DR3. In addition, in the cross-section, an angle formed between the side surface of the first portion RES1 of the resin layer RES and the upper surface of the first portion RES1 of the resin layer RES may be substantially a right angle. The first portion RES1 of the resin layer RES may correspond to the adhesive layer ADL of FIG. 2.

After the process of cutting the resin layer RES, the cover window (CW, refer to FIG. 2) may be provided on the first portion RES1 of the resin layer RES. The first portion RES1 of the resin layer RES may attach the anti-reflection layer POL and the cover window CW. That is, the cover window CW may be attached to the upper surface of the anti-reflection layer POL through the first portion RES1 of the resin layer RES. Accordingly, the display device DD of FIG. 2 including the display panel DP, the cover panel CPL, the anti-reflection layer POL, and the cover window CW may be formed.

After the resin layer RES is cut by the cutting member 200, the guide plate 100 may be spaced apart from the display panel DP and the anti-reflection layer POL. The second portion RES2 of the resin layer RES remaining on the upper surface of the guide plate 100 may be removed by a cleaning process. In an embodiment, for example, the guide plate 100 may be cleaned by a method utilizing CO₂, a laser pulse wave method, or a method utilizing a chemical solution, or the like, and the second portion RES2 of the resin layer RES may be removed.

The guide plate 100 that has been cleaned may be reused in the manufacturing process of the display device DD. The contacting the guide plate 100 with the display panel DP and the anti-reflection layer POL (S200), the forming the resin layer RES on the anti-reflection layer POL (S300), and the cutting the resin layer RES using the cutting member 200 (S400) may be repeatedly performed.

As illustrated in FIG. 13, as the cutting the resin layer RES using the cutting member 200 is repeatedly performed, a residual organic material (IMP, hereinafter referred to as a residue) may adhere to the blade portion KNP of the cutting member 200 during the process of cutting the resin layer RES. When the resin layer RES is cut using the blade portion KNP to which the residue IMP is adhered, the side surface of the first portion RES1 of the resin layer RES may not be aligned with an edge of the display panel DP in the thickness direction of the display panel DP. In other words, a burr may be formed on the side surface of the first portion RES1 of the resin layer RES, and the burr may cause a process defect in which bubbles are generated.

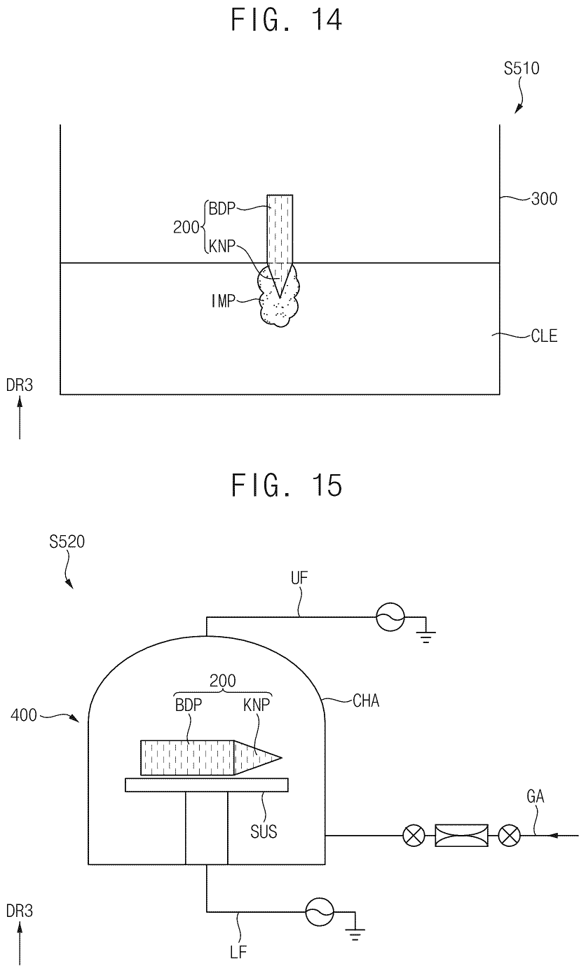

To remove the residue IMP adhered to the blade portion KNP and to suppress the phenomenon of the residue IMP sticking to the blade portion KNP in the process of cutting the resin layer RES, the method for manufacturing the display device according to an embodiment of the disclosure may further include processing the blade portion KNP of the cutting member 200. Hereinafter, the processing the blade portion KNP of the cutting member 200 will be described in detail with reference to FIGS. 14, 15, 16, and 17.

Referring to FIGS. 14, 15, 16, and 17, the processing the blade portion KNP of the cutting member 200 may include removing the residue IMP adhered to the blade portion KNP (S510), plasma treating the cutting member 200 (S520), and coating the blade portion KNP of the cutting member 200 with a hydrophobic material HPM (S530).

In an embodiment, as illustrated in FIG. 14, the blade portion KNP of the cutting member 200 may be cleaned by a cleaning solution CLE (S510).

A first tank 300 may accommodate the cleaning solution CLE. In an embodiment, the cleaning solution CLE may be an etchant including ethanol. However, the disclosure is not limited thereto. In another embodiment, the cleaning solution CLE may be an etchant including fluorine (F). By immersing the cutting member 200 in the cleaning solution CLE accommodated in the first tank 300, the blade portion KNP of the cutting member 200 may be cleaned, and the residue IMP adhered to the blade portion KNP may be removed.

After immersing the cutting member 200 in the cleaning solution CLE, a process of cleaning the cutting member 200 using a cleaning cloth may be performed. In an embodiment, for example, the cleaning cloth may be a dust-free cloth. That is, the cleaning cloth may be a cloth that does not generate dust or the like by friction, and may be, for example, a nylon-based cloth.

In an embodiment, the process of cleaning the cutting member 200 using the cleaning cloth may include a process of wet cleaning the cutting member 200 using a first dust-free cloth soaked in ethanol and a process of dry cleaning the cutting member 200 using a second dust-free cloth. In the process of wet cleaning the cutting member 200 using the first dust-free cloth, the residue IMP that are not removed by the cleaning solution CLE may be additionally removed. In the process of dry cleaning the cutting member 200 using the second dust-free cloth, the cleaning solution CLE on the cutting member 200 may be removed.

In an embodiment, as illustrated in FIG. 15, the cutting member 200 may be plasma treated by a plasma treatment part 400 (S520).

The plasma treatment part 400 may include a chamber CHA, a susceptor SUS, an upper power source UF, a lower power source LF, and a gas supply GA. The chamber CHA may define a space in which the process of treating the cutting member 200 is performed. The susceptor SUS may be arranged inside the chamber CHA. The cutting member 200 may be loaded on the susceptor SUS. The upper power source UF may be connected to an upper portion of the chamber CHA, and the lower power source LF may be connected to the susceptor SUS. The upper power source UF and the lower power source LF may generate plasma inside the chamber CHA. The gas supply GA may supply a reaction gas inside the chamber CHA. In an embodiment, for example, the reaction gas may include hydrogen (H₂), but the disclosure is not limited thereto. In another embodiment, for example, the reaction gas may include oxygen (O₂).

As the cutting member 200 is plasma treated by the plasma treatment part 400, the hydrophobic material HPM may be more smoothly adsorbed on the cutting member 200 in the coating the blade portion KNP of the cutting member 200 with the hydrophobic material HPM (S530), which is described below.

In an embodiment, as illustrated in FIGS. 16 and 17, the blade portion KNP of the cutting member 200 may be coated with the hydrophobic material HPM (S530).

A second tank 500 may accommodate a hydrophobic coating solution HPL. The hydrophobic coating solution HPL may include a material having a low surface energy. In an embodiment, the hydrophobic coating solution HPL may include octadecyltrichlorosilane. In such an embodiment, the hydrophobic material HPM may be coated on the blade portion KNP of the cutting member 200 by immersing the blade portion KNP of the cutting member 200 in the octadecyltrichlorosilane solution accommodated in the second tank 500. However, the disclosure is not limited thereto. In an embodiment, the hydrophobic coating solution HPL may include a silica aerogel. In such an embodiment, the hydrophobic material HPM may be coated on the blade portion KNP of the cutting member 200 by immersing the blade portion KNP of the cutting member 200 in a solution in which the silica aerosol is dissolved in a solvent such as methanol, ethanol, isopropyl alcohol (IPA), or the like. In an embodiment, for example, the coated hydrophobic material HPM may include a siloxane-based polymer. However, the disclosure is not limited thereto, and the coated hydrophobic material HPM may include a fluorine-based polymer. Accordingly, the blade portion KNP of the cutting member 200 may have a water-repellent property.

After coating the blade portion KNP of the cutting member 200 with the hydrophobic material HPM, a process of dry cleaning the cutting member 200 using a cleaning cloth (e.g., a dust-free cloth) may be performed. Accordingly, the hydrophobic coating solution HPL remaining on the cutting member 200 may be removed.

Referring to FIG. 18, the resin layer RES may be cut along the edge ED of the display panel DP using the cutting member 200 coated with the hydrophobic material HPM (S600).

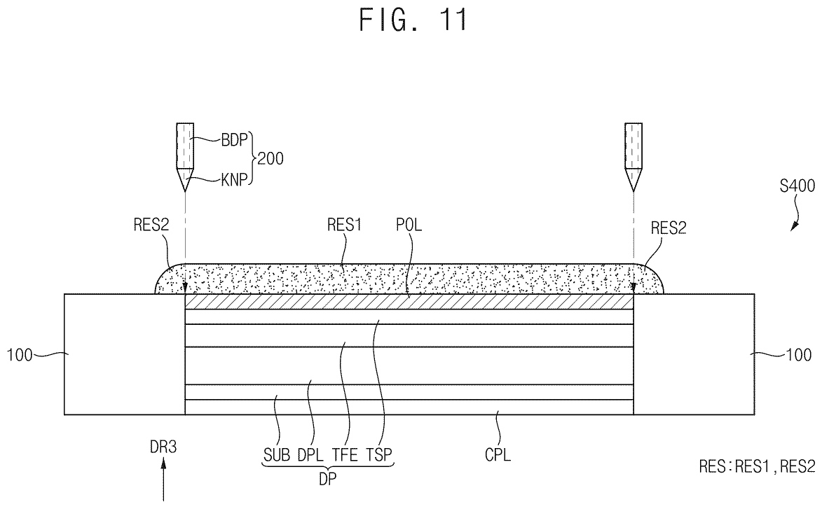

The cutting member 200 may cut a portion of the resin layer RES that overlaps the first side 11 and the third side 13 of the display panel DP in a plan view. In addition, the cutting member 200 may cut a portion of the resin layer RES that overlaps the second side 12 and the fourth side 14 of the display panel DP in a plan view. The first portion (RES1, refer to FIG. 11) of the resin layer RES overlapping the display panel DP and the anti-reflection layer POL in a plan view may remain, and the second portion (RES2, refer to FIG. 11) of the resin layer RES overlapping the guide plate 100 in a plan view may be removed.

Referring again to FIGS. 14, 15, 16, 17, and 18, an apparatus for manufacturing a display device according to an embodiment of the disclosure may include the guide plate 100 that may contact the display panel DP and the anti-reflection layer POL, the cutting member 200 that cuts the resin layer RES along the edge ED of the display panel DP, the first tank 300 that accommodates the cleaning solution CLE for removing the residue IMP adhered to the cutting member 200, the plasma treatment part 400 that performs plasma treatment on the cutting member 200, and the second tank 500 that accommodates the hydrophobic coating solution HPL for coating the cutting member 200 with the hydrophobic material HPM.

As the hydrophobic material HPM is coated on the blade portion KNP of the cutting member 200, the adhesive force between the blade portion KNP and the resin layer RES may be relatively reduced. That is, the hydrophobic material HPM may reduce the adhesive force between the cutting member 200 and the resin layer RES. Accordingly, in the process of cutting the resin layer RES, the phenomenon of the residue (IMP, refer to FIG. 13) sticking to the blade portion KNP of the cutting member 200 may be suppressed (effectively prevented or substantially minimized). Accordingly, when the resin layer RES is cut using the blade portion KNP coated with the hydrophobic material HPM, the side surfaces of the first portion RES1 of the resin layer RES (i.e., a cut surface of the resin layer RES) may be substantially aligned with an edge of the display panel DP in the thickness direction of the display panel DP. In addition, in a cross-section, the angle formed between the side surface of the first portion RES1 of the resin layer RES and the upper surface of the first portion RES1 of the resin layer RES may be substantially a right angle. As a result, the formation of the burr on the side surface of the first portion RES1 of the resin layer RES may be prevented, and a process defect caused by the burr may be suppressed.

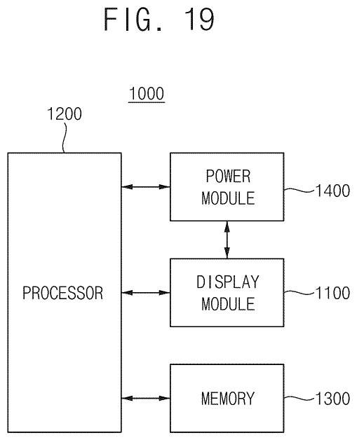

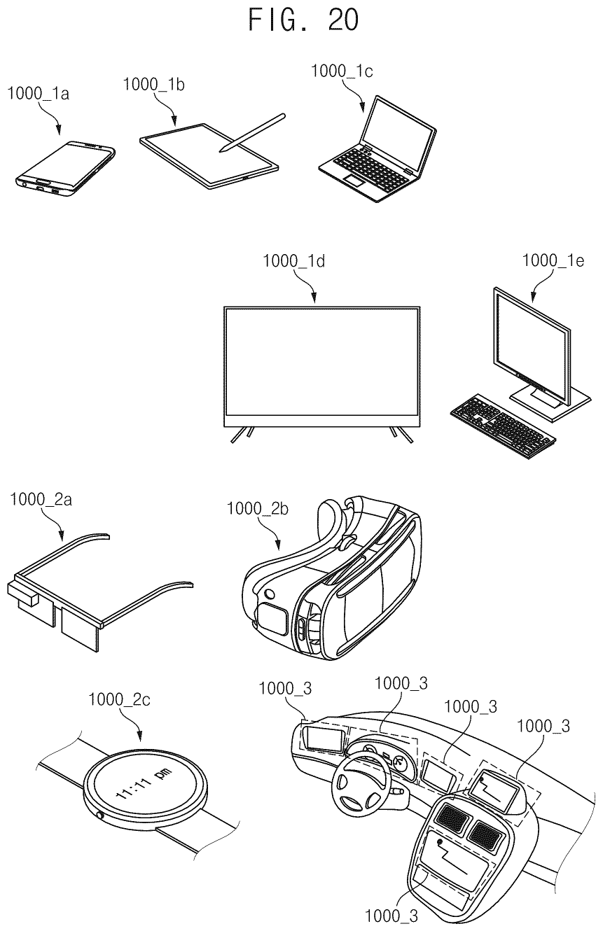

FIG. 19 is a block diagram of an electronic device according to an embodiment of the disclosure.

Referring to FIG. 19, an electronic device 1000 according to an embodiment may include a display module 1100, a processor 1200, a memory 1300, and a power module 1400. The display device according to an embodiment may be applied to a variety of electronic devices. The electronic device 1000 according to an embodiment may include the display device described above, and may further include modules or devices having other additional functions in addition to the display device.

The processor 1200 may include at least one selected from a central processing unit (CPU), an application processor (AP), a graphic processing unit (GPU), a communication processor (CP), an image signal processor (ISP), and a controller.

The memory 1300 may store data information required for operation of the processor 1200 or the display module 1100. When the processor 1200 executes an application stored in the memory 1300, an image data signal and/or a input control signal may be transmitted to the display module 1100, and the display module 1100 may process the received signals and may output image information through a display screen.

The power module 1400 may include a power supply module, such as a power adapter or a battery device, etc., and a power conversion module that converts power supplied by the power supply module to generate the power required for operation of the electronic device 1000. That is, the power module 1400 may provide power to the display device according to the embodiments described above.

At least one of the components of the electronic device 1000 described above may be included in the display device according to the embodiments described above. In addition, some of the individual modules that are functionally included in one module may be included in the display device and others may be provided separately from the display device. In an embodiment, for example, the display device may include the display module 1100, and the processor 1200, the memory 1300, and the power module 1400 may be provided in the form of other devices in the electronic device 1000 other than the display device.

FIG. 20 is a schematic diagram of an electronic device according to various embodiments.

Referring to FIG. 20, various electronic devices to which a display device according to the embodiments is applied may include image display electronic devices such as a smartphones 1000_1a, a tablet PC 1000_1b, a laptop 1000_1c, a television 1000_1d, a desk monitor 1000_1e, etc., wearable electronic devices including display modules such as a smart glasses 1000_2a, a head-mounted display 1000_2b, and a smart watch 1000_2c, etc., and vehicle electronic devices (1000_3) including display modules such as a CID (center information display) which may be disposed on a instrument panel, a center fascia, and a dashboard of an automobile and a room mirror display, etc.

Embodiments of the disclosure may be applied to various display devices such as display devices for vehicles, ships and aircraft, portable communication devices, display devices for exhibition or information transmission, medical display devices, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
a guide plate provided to contact a display panel;
a cutting member which cuts a resin layer formed on the display panel along an edge of the display panel;
a first tank which accommodates a cleaning solution for removing a residue of the resin layer adhered to the cutting member;
a plasma treatment part which performs a plasma treatment on the cutting member; and
a second tank which accommodates a hydrophobic coating solution for coating the cutting member with a hydrophobic material.

2. The apparatus of claim 1, wherein the cutting member cuts the resin layer in a way such that a side surface of the resin layer is substantially perpendicular to an upper surface of the resin layer.

3. The apparatus of claim 1, wherein the cutting member cuts the resin layer in a way such that a side surface of the resin layer is substantially aligned with the edge of the display panel in a thickness direction of the display panel.

4. The apparatus of claim 1, wherein the hydrophobic coating solution comprises octadecyltrichlorosilane.

5. The apparatus of claim 1,
wherein the cutting member comprises a body portion and a blade portion which is connected to the body portion and cuts the resin layer, and
wherein the hydrophobic material is coated on the blade portion.

6. The apparatus of claim 1, wherein the hydrophobic material comprises a siloxane-based polymer or a fluorine-based polymer.

7. The apparatus of claim 1, wherein the hydrophobic material reduces an adhesive force between the cutting member and the resin layer.

8. A method of manufacturing a display device, the method comprising:
contacting a guide plate with a display panel and an anti-reflection layer arranged on the display panel;
forming a resin layer on the guide plate and the anti-reflection layer;
cutting the resin layer along an edge of the display panel using a cutting member;
removing a residue of the resin layer adhered to the cutting member;
performing a plasma treatment on the cutting member;
coating a hydrophobic material on the cutting member; and
cutting another resin layer formed on another anti-reflection layer different from the anti-reflection layer using the cutting member coated with the hydrophobic material.

9. The method of claim 8, wherein the coating the hydrophobic material on the cutting member comprises immersing the cutting member in a hydrophobic coating solution.

10. The method of claim 9, wherein the hydrophobic coating solution comprises octadecyltrichlorosilane.

11. The method of claim 8,
wherein the cutting member comprises a body portion and a blade portion which is connected to the body portion and cuts the resin layer, and
wherein the hydrophobic material is coated on the blade portion.

12. The method of claim 8, wherein the hydrophobic material comprises a siloxane-based polymer or a fluorine-based polymer.

13. The method of claim 8, wherein the cutting member coated with the hydrophobic material cuts the resin layer in a way such that a side surface of the resin layer is substantially perpendicular to an upper surface of the resin layer.

14. The method of claim 8, wherein the cutting member coated with the hydrophobic material cuts the resin layer in a way such that a side surface of the resin layer is substantially aligned with the edge of the display panel in a thickness direction of the display panel.

15. The method of claim 8, wherein in the forming the resin layer on the guide plate and the anti-reflection layer, the resin layer comprises a first portion which overlaps the anti-reflection layer in a plan view and a second portion which is connected to the first portion and overlaps the guide plate in the plan view, and
wherein the first portion of the resin layer has a substantially flat upper surface.

16. The method of claim 8, wherein a side surface of the guide plate contacts a side surface of the display panel and a side surface of the anti-reflection layer in the contacting the guide plate with the display panel and the anti-reflection layer.

17. The method of claim 8, wherein the guide plate entirely surrounds the display panel and the anti-reflection layer in a plan view in the contacting the guide plate with the display panel and the anti-reflection layer.

18. The method of claim 8, wherein a level of an upper surface of the guide plate is substantially the same as a level of an upper surface of the anti-reflection layer.

19. The method of claim 8, further comprising:
separating the guide plate from the display panel and the anti-reflection layer and cleaning the guide plate after the cutting the resin layer along the edge of the display panel.

20. An electronic device comprising:
a display device manufactured according to the method of claim 8; and
a processor which transmits an image data signal and an input control signal to the display device.
